(19) United States
(12) Patent Application Publication
(10) Pub. No.: US 2024/0128128 A1
(43) Pub. Date: Apr. 18, 2024

(54) METHOD AND APPARATUS FOR DETECTING CLUSTERS OF WAFER DEFECTS

(71) Applicant: SAMSUNG ELECTRONICS CO, LTD., Suwon-si (KR)

(72) Inventors: KIBUM LEE, Suwon-si (KR); Taesoo Shin, Suwon-si (KR); Seulgi Ok, Suwon-si (KR); Sungwook Hwang, Suwon-si (KR)

(21) Appl. No.: 18/474,887

(22) Filed: Sep. 26, 2023

(30) Foreign Application Priority Data
Oct. 18, 2022 (KR) 10-2022-0134473
Jan. 31, 2023 (KR) 10-2023-0013181

(51) Int. Cl. H01L 21/66

(52) U.S. Cl. CPC H01L 22/12; H01L 22/34

(57) ABSTRACT

A method of detecting clusters of defects includes measuring each of a plurality of wafers to obtain a plurality of wafer level maps of a plurality of wafer measurement points, creating a composite wafer level map by combining the plurality of wafer level maps, dividing the composite wafer level map into a plurality of grid areas, obtaining a plurality of target grid areas from the plurality of grid areas using unique values of the plurality of grid areas, grouping the plurality of target grid areas into a plurality of target grid clusters corresponding to the clusters of defects, and obtaining a detection priority for each of the plurality of target grid clusters based on the unique value of the plurality of target grid areas included in the plurality of target grid clusters.

### CROSS-REFERENCE TO RELATED APPLICATIONS

This application is based on and claims priority under 35 U.S.C. § 119 to Korean Patent Application No. 10-2022-0134473, filed on Oct. 18, 2022, and Korean Patent Application No. 10-2023-0013181, filed on Jan. 31, 2023, in the Korean Intellectual Property Office, the disclosures of which are incorporated by reference herein in their entirety.

### TECHNICAL FIELD

The inventive concept relates to a method of detecting clusters of wafer defects, and more particularly, to a method of detecting clusters of defects on a wafer using data obtained by measuring a rear surface of the wafer, and a defect cluster detection apparatus.

### DESCRIPTION OF RELATED ART

In a process of manufacturing a semiconductor device, hot spot defects may be caused by particles deposited on a rear surface of a semiconductor wafer. The rear surface of the semiconductor wafer may be continuously contaminated by particles in the environment. Typically, these particles may be generated due to friction and vibration conditions associated with the manufacturing process. Due to forces and pressures applied between the wafer and a chuck during photo process, a local surface of the wafer may deflect and a hot spot may occur in an area where a particular has been deposited on the rear surface of the wafer.

In a case where a size of the hot spot is greater than depth of focus (DOF) range, a pattern may not be properly formed on the wafer during the photo process, resulting in an out-of-focus condition and hot spot defects. For example, due to the out-of-focus condition, a quality of the semiconductor device may decrease, and yield of the semiconductor wafer may decrease.

### SUMMARY

The inventive concept is related to the detection of clusters of defects on a rear surface of a wafer at an early stage, thereby enabling early detection of a process or manufacturing equipment that may be a source of the defects.

According to an aspect of the inventive concept, there is provided a method of detecting clusters of defects, which includes measuring each of a plurality of wafers to obtain a plurality of wafer level maps of a plurality of wafer measurement points, creating a composite wafer level map by combining the plurality of wafer level maps, dividing the composite wafer level map into a plurality of grid areas, obtaining a plurality of target grid areas from the plurality of grid areas using unique values of the plurality of grid areas, grouping the plurality of target grid areas into a plurality of target grid clusters, and obtaining a detection priority for each of the plurality of target grid clusters based on the unique values of the plurality of target grid areas included in the plurality of target grid clusters.

According to another aspect of the inventive concept, there is provided an apparatus for detecting clusters of wafer defects, which includes a memory storing a program for detecting the wafer defects, and a processor configured to execute the program stored in the memory to measure a height at each of a plurality of wafer measurement points on each of a plurality of wafers to obtain a plurality of wafer level maps, create a composite wafer level map by combining the plurality of wafer level maps, divide the composite wafer level map into a plurality of grid areas, obtain a plurality of target grid areas from the plurality of grid areas using unique values of the plurality of grid areas, group the plurality of target grid areas into a plurality of target grid clusters corresponding to the clusters of defects, obtain a detection priority for each of the plurality of target grid clusters based on the unique values of the plurality of target grid areas included in the plurality of target grid clusters, and select a set of wafer defects to analyze among the wafer defects based on the detection priorities.

According to another aspect of the inventive concept, there is provided a method of detecting clusters defects, which includes storing a plurality of wafer level maps indicating locations of the wafer defects on rear surfaces of a plurality of wafers, creating a composite wafer level map by combining the plurality of wafer level maps, storing information of a plurality of grid areas dividing the composite wafer level map, storing information of a plurality of target grid areas having unique values of the plurality of grid areas, storing information on a plurality of target grid clusters corresponding to groups of the plurality of target grid areas and corresponding to the clusters of defects, storing detection priorities of the plurality of target grid clusters obtained using the unique values of the plurality of target grid areas included in the plurality of target grid clusters, and selecting a set of wafer defects to analyze among the wafer defects according to the detection priorities.

### BRIEF DESCRIPTION OF THE DRAWINGS

Embodiments will be more clearly understood from the following detailed description taken in conjunction with the accompanying drawings in which:

FIG. 1 is a diagram illustrating a wafer defect cluster detection system according to an embodiment;

FIG. 2 is a flowchart illustrating a method of detecting clusters of wafer defects according to an embodiment;

FIG. 3 is a flowchart for explaining a method of obtaining a wafer level map according to an embodiment;

FIG. 4 is a diagram for explaining an operation of measuring a wafer according to an embodiment;

FIG. 5 is a diagram for explaining a wafer measurement point according to an embodiment;

FIG. 6 is a diagram for explaining a composite wafer level map according to an embodiment;

FIG. 7 is a diagram for explaining an operation of dividing a composite wafer level map into grid areas according to an embodiment;

FIG. 8 is a flowchart illustrating a method of dividing a composite wafer level map into grid areas according to an embodiment;

FIG. 9 is a diagram for explaining an operation of obtaining target grid areas according to an embodiment;

FIG. 10 is a diagram illustrating target grid areas according to an embodiment;

FIG. 11A and FIG. 11B are diagrams illustrating target grid clusters according to embodiments;

FIG. 12 is a diagram for explaining an operation of obtaining detection priorities of target grid clusters according to an embodiment;

FIG. 13 is a diagram for explaining an operation of correcting a target grid cluster according to an embodiment;

FIG. 14 is a diagram for explaining an operation of performing a close-range search according to an embodiment;

FIG. 15 is a flowchart illustrating a method of detecting clusters of wafer defects according to an embodiment; and

FIG. 16 is a diagram illustrating a defect cluster detection apparatus according to an embodiment.

### DETAILED DESCRIPTION

Hereinafter, embodiments of the inventive concept will be described in detail with reference to the accompanying drawings.

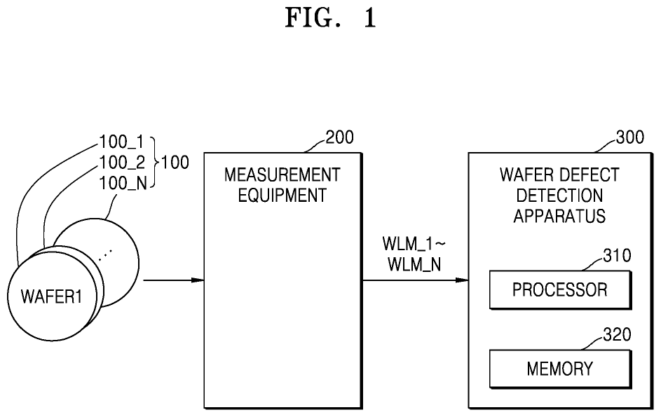

FIG. 1 is a diagram illustrating a wafer defect cluster detection system according to an embodiment.

During a process of manufacturing wafers, a photo process may be performed on the wafers 100 several times. The wafers 100 may be contaminated by particles. These particles may be generated by friction and vibration conditions associated with each photo process. These photo processes may be referred to as photolithography or photolithography processes. Each of the wafers 100 may include areas with a height equal to or greater than a threshold height. Areas where particles have been deposited on a rear surface of the wafers may result in defect points or defect regions where the area has a height greater than a threshold height.

Referring to FIG. 1, defects due to particles may occur in one or more of the wafers 100 during any of the several photo processes performed. Measurement equipment 200 may measure each of the wafers 100 at a completion of each photo process. The measurement equipment 200 may generate wafer level maps WLM_1 to WLM_N. For example, following each photo process of the first wafer 100_1, the measurement equipment 200 may generate the first wafer level map WLM_1. The wafer level map may include data on defect points measured on each of the wafers 100. The wafer level map may indicate locations and heights of the defect points.

In some embodiments, the measurement equipment 200 may obtain raw data including the locations and heights of measurement points by measuring each of the wafers 100. A measurement point may refer to a position measured by the measurement equipment 200 on one or more of the wafers 100. The measurement equipment 200 may generate a wafer level map using data indicating a height equal to or greater than threshold height among raw data, that is, defect point data. The data indicating that a height of a measurement point is above the threshold height may be referred to as wafer level data or defect point data. The wafer level data may include the locations and heights of defects.

For example, as shown in FIG. 1, the measurement equipment 200 may measure each of the N wafers 100 and generate the wafer level maps WLM_1 to WLM_N including data for measurement points with heights above the threshold height. The measurement equipment 200 may transmit the wafer level maps WLM_1 to WLM_N to a defect cluster detection apparatus 300.

The defect cluster detection apparatus 300 may include a processor 310 and a memory 320. For example, the defect cluster detection apparatus 300 may be a computing device such as a personal computer, a mobile phone, or a server. The defect cluster detection apparatus 300 may be a module in which a plurality of processing cores and a memory are mounted on a substrate as independent packages, and may be a System-on-Chip (SoC) in which a plurality of processing cores and memory are integrated into a single chip.

The processor 310 may communicate with the memory 320 and execute instructions. In some embodiments, the processor 310 may execute a program stored in the memory 320. The program may include a series of instructions. The processor 310 may be any hardware capable of executing instructions, and may be referred to as an application processor (AP), a communication processor (CP), a central processing unit (CPU), a processor core, a core, or the like.

The processor 310 may communicate with the memory 320. The memory 320 may be accessed by the processor 310, and may store software elements executable by the processor 310. By a non-limiting example, the software element may include a software component, program, application, computer program, application program, system program, software development program, machine program, operating system (OS) software, middleware, firmware, software module, routine, subroutine, function, method, procedure, software interface, application program interface (API), instruction set, computing code, computer code, code segment, computer code segment, word, value, symbol, or combination of two or more thereof.

The memory 320 may be any hardware configured to store information, and may be accessible by the processor 310. For example, the memory 320 may include read only memory (ROM), random-access memory (RAM), dynamic random access memory (DRAM), double-data-rate dynamic random access memory (DDR-DRAM), synchronous dynamic random access memory (SDRAM), static random access memory (SRAM), magneto-resistive random access memory (MRAM), programmable read only memory (PROM), erasable programmable read only memory (EPROM), electrically erasable programmable read only memory (EEPROM), flash memory, polymer memory, phase change memory, ferroelectric memory, silicon-oxide-nitride-oxide-silicon (SONOS) memory, magnetic card/disk, optical card/disk, or combination of two or more thereof.

The memory 320 may store the N wafer level maps WLM_1 to WLM_N corresponding to each of the N wafers 100.

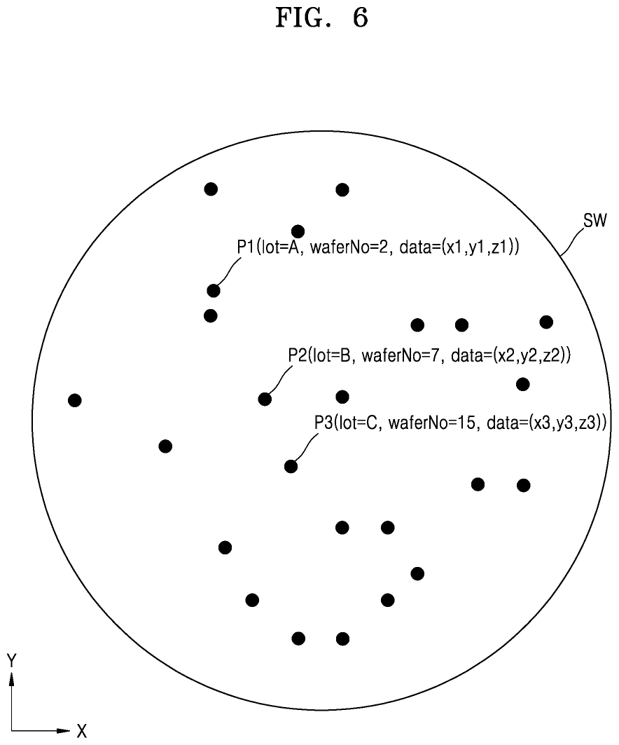

The defect cluster detection apparatus 300 may combine the stored N wafer level maps WLM_1 to WLM_N. The defect cluster detection apparatus 300 may create a composite wafer level map by combining the wafer level maps WLM_1 to WLM_N. For example, the defect cluster detection apparatus 300 may generate the composite wafer level map by combining the wafer level maps WLM_1 to WLM_N corresponding to each of the wafers 100 and displaying combination on a single plane. In other words, the composite wafer level map may indicate the positions of defect points generated in the plurality of wafers 100 on a single plane. The composite wafer level map may be referred to as a composite map. As shown in FIG. 6, the composite wafer level map may include data of defect points generated on different ones of the wafers 100.

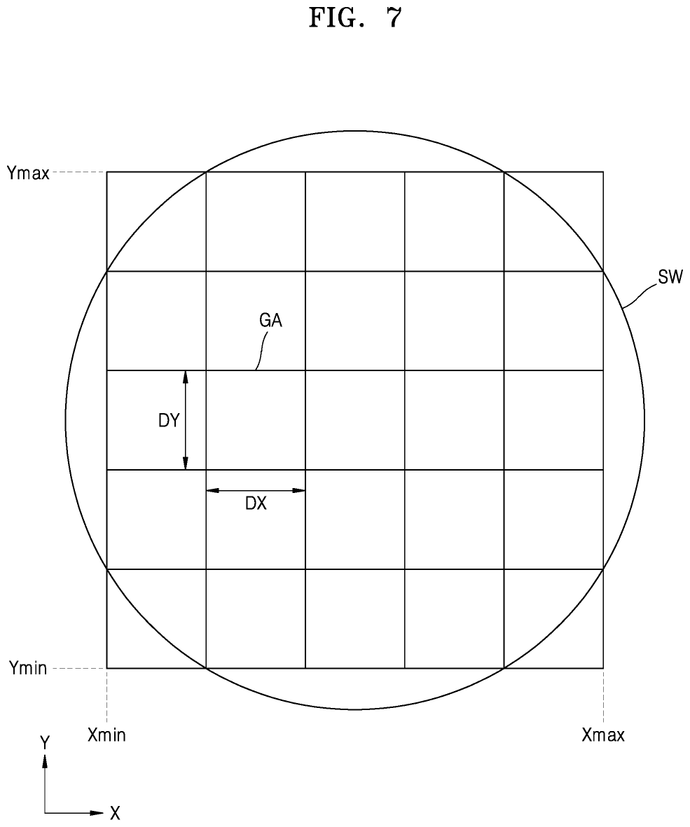

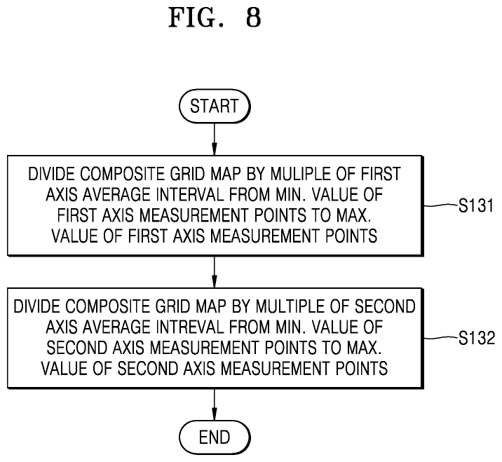

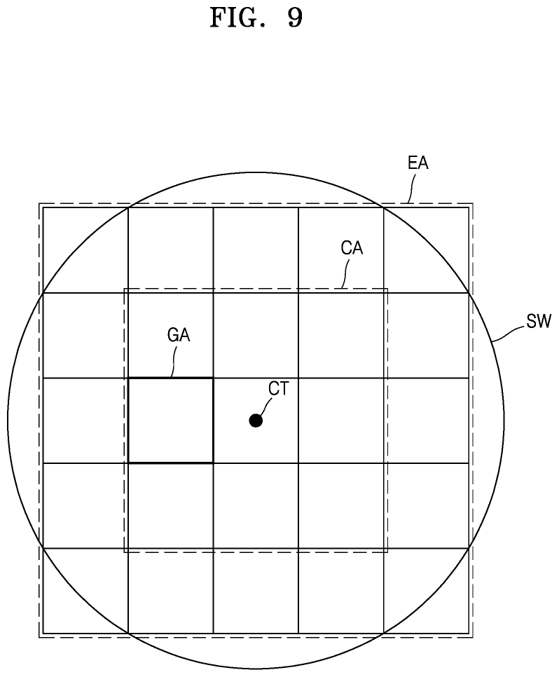

The defect cluster detection apparatus 300 may divide the composite wafer map into a plurality of grid areas. An operation of dividing the composite wafer map into a plurality of grid areas is described herein with reference to FIG. 7 and FIG. 8. The defect cluster detection apparatus 300 may acquire a plurality of target grid areas based on a unique value of the plurality of grid areas. As described herein with reference to FIG. 9, the unique value may mean a value indicating a degree of occurrence of defects in a certain grid area. The plurality of target grid areas may refer to grid areas that are subject to defect analysis. The grid areas subject to defect analysis among the plurality of grid areas may be identified as areas including a measure of defects, for example, a threshold number of defects per grid area.

The defect cluster detection apparatus 300 may group the plurality of neighboring target grid areas into a target grid cluster. The defect cluster detection apparatus 300 may obtain detection priorities of the target grid clusters depending on the degree of defects occurring in the target grid clusters.

The defect cluster detection apparatus 300 may analyze the wafer defects according to the detection priorities. The defect cluster detection apparatus 300 may analyze the wafer defects so that processes and process facilities that cause defects on the rear surface of the wafer can be tracked at an early stage, and a yield of semiconductor products from the wafer can be improved.

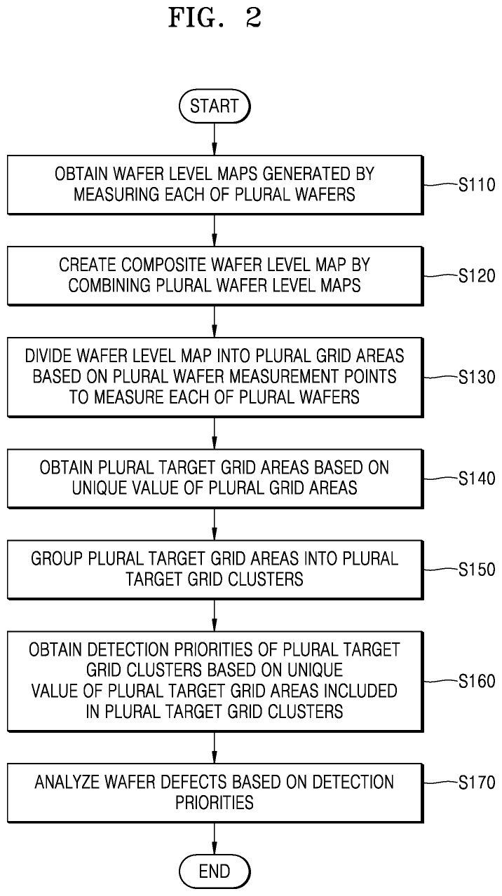

FIG. 2 is a flowchart illustrating a method of detecting wafer defects according to an embodiment.

Referring to FIG. 2, the method of detecting wafer defects according to an embodiment may include operations S110 to S170. FIG. 2 may be described with reference to FIG. 1.

In operation S110, the plurality of wafer level maps WLM_1 to WLM_N may be obtained by measuring each of the plurality of wafers 100. The plurality of wafer level maps WLM_1 to WLM_N may include wafer level data, and the wafer level data may include the locations and heights of different defects.

In operation S120, a composite wafer level map may be created by combining the plurality of wafer level maps WLM_1 to WLM_N. The composite wafer level map may include data indicating the locations of defect points occurring on each of the plurality of wafers. The composite wafer level map may be displayed showing the locations of defect points occurring on each of the plurality of wafers on a plane.

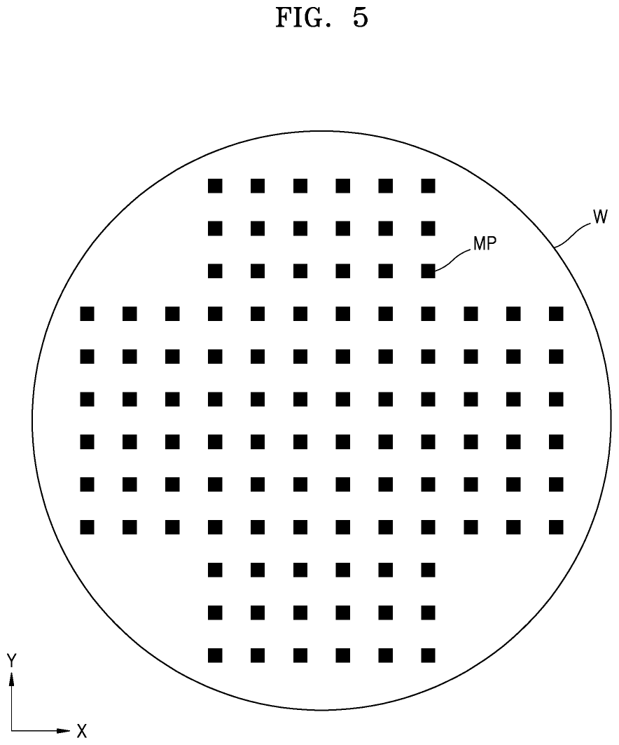

In operation S130, the composite wafer level map may be divided into a plurality of grid areas. The composite wafer level map may be divided into the plurality of grid areas based on a plurality of wafer measurement points obtained by measuring each of the plurality of wafers 100. Referring to FIG. 5, the wafer measurement points MP at which the plurality of wafers 100 are measured may indicate locations where the plurality of wafers are measured. The composite wafer level map may be divided into the plurality of grid areas based on an interval of wafer measurement points. For example, as described with reference to FIG. 8, the grid areas may be divided into intervals of the measurement points.

In operation S140, a plurality of target grid areas may be obtained. The plurality of target grid areas may be obtained based on a unique value of the plurality of grid areas. The unique value may include at least one of a number of unique lots of wafers, a number of unique wafers in the unique lots, or a number of unique data points on the wafers. A photo process may be performed on the wafers in lot units, and the number of unique lots may indicate the number of defective lots. The number of unique wafers may indicate the number of defective wafers among a plurality of lots, and the number of unique data points may indicate the number of defect points on each of wafers.

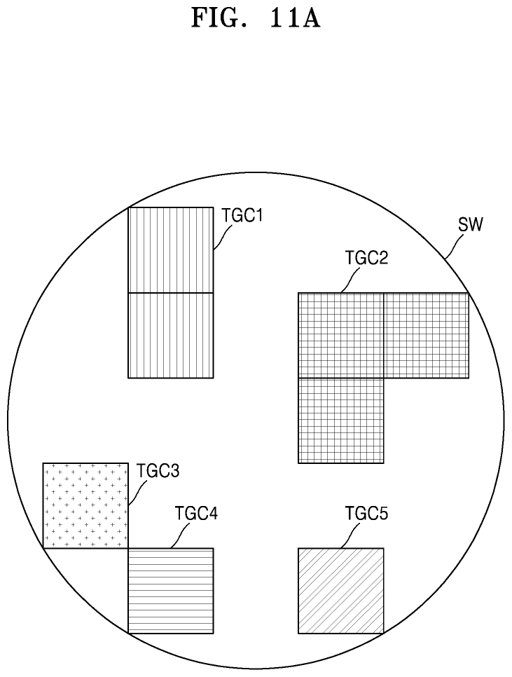

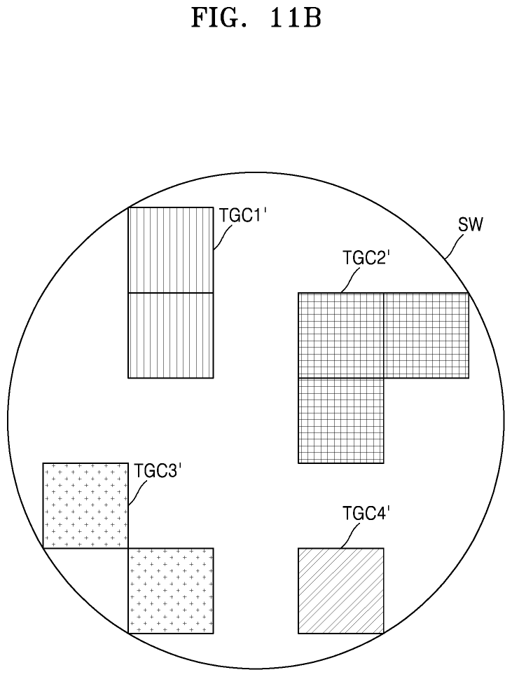

In operation S150, the plurality of target grid areas may be grouped into a plurality of target grid clusters. The plurality of target grid clusters may be created by grouping adjacent target grid areas among the target grid areas. A method of grouping the target grid areas may be performed in various ways as will be described with reference to FIG. 11A and FIG. 11B. In some embodiments, respective target grid areas may be adjacent on a plane, and these adjacent target grid areas may be grouped into a target grid cluster. For example, two target grid areas may be adjacent on a same plane, and these adjacent target grid areas may be grouped into a same target grid cluster. In another embodiment, respective target grid areas adjacent to a point may be grouped into a target grid cluster. For example, target grid areas may be adjacent when they share a same point (e.g., corners of the target grid areas meet), and these adjacent target grid areas may be grouped into a same target grid cluster.

In operation S160, the detection priorities of the plurality of target grid clusters may be obtained. The detection priority of a target grid cluster may be obtained based on the unique value of the plurality of target grid areas included in the target grid cluster. In the case that the number of defect points in the target grid areas included in the target grid cluster is large, the unique value of the target grid area may also be large. In other words, when many defects occur, the detection priorities may be higher than when the number of defects is small.

In operation S170, the plurality of target grid clusters and the detection priority for each of the plurality of target grid clusters may be output to a wafer defect analysis system for analyzing the wafer defects based on the detection priorities. In operation S170, the defects of the wafers may be analyzed by the wafer defect analysis system according to the detection priorities of the target grid clusters. For example, operation S170 may include selecting a set of wafer defects to analyze among the wafer defects based on the detection priorities. By analyzing the defects of the wafers starting with the target grid clusters having high priorities, process equipment or operations that may cause defects on the rear surface of wafer may be determined and tracked. For example, the wafer defects may be analyzed in an order based on the detection priorities. The analysis of these defects, e.g., defects in a target grid cluster having a high priority, may be performed at an early stage, for example, at each photo process operation. For example, the defects in a target grid cluster having a high priority may be the first set of defects to exhibit a pattern associated with a known pattern of defects. In another example, the defects in a target grid cluster having a high priority may represent sufficient data points to support a statistical analysis. A method of analyzing the defects according to the detection priorities of the target grid clusters may be, for example, a commonality analysis method for tracking process equipment or operations that may generate defects based on location information of a target grid cluster. However, the commonality analysis method is an example, and the inventive concept is not limited thereto.

According to an embodiment, the target grid clusters and the detection priorities may improve a wafer analysis method and apparatus, for example, enabling early detection and tracking of processes and process equipment that may cause defects on a rear surface of a wafer. For example, clusters that are likely to be useful to a wafer analysis method and apparatus, that is, the target grid clusters having high detection priorities, may be detected early, and lead to early detection of the source of defects may enable early intervention, which my increase a yield of a semiconductor manufacturing process.

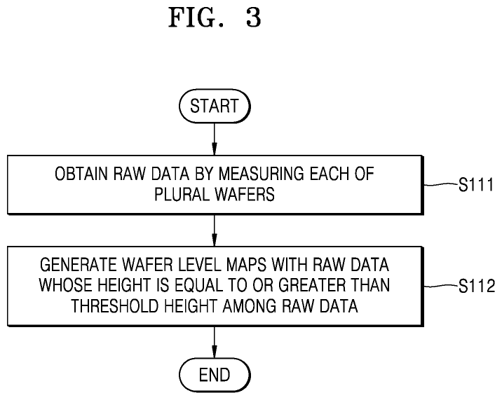

FIG. 3 is a flowchart for explaining a method of obtaining a wafer level map according to an embodiment. FIG. 3 may be described with reference to FIG. 1.

In operation S111, raw data may be obtained by measuring each of the plurality of wafers 100. The raw data including locations and heights of measurement points may be acquired by measuring each of the plurality of wafers 100.

In operation S112, the wafer level map may be generated from wafer level data. The wafer level data may indicate that a height in the raw data is equal to or greater than a threshold height. The wafer level maps WLM_1 to WLM_N may be generated from the raw data indicating heights equal to or greater than the threshold height, e.g., 10 nm, among the raw data acquired in step S111.

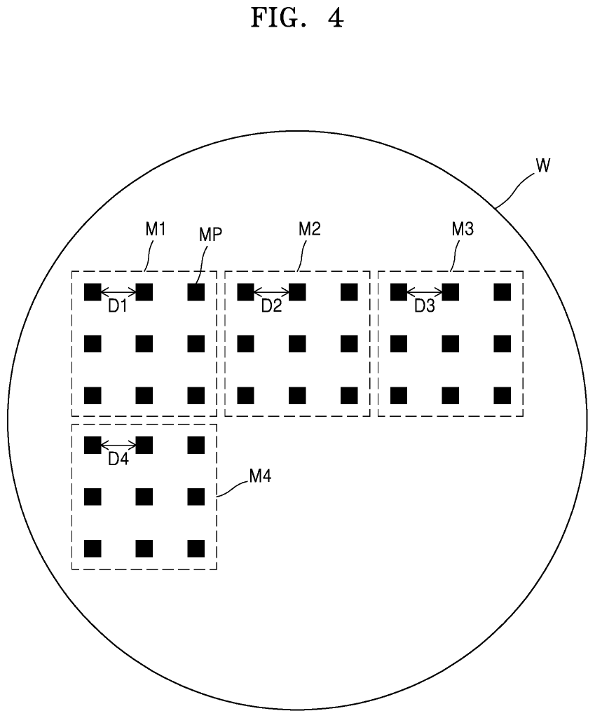

FIG. 4 is a diagram for explaining an operation of measuring a wafer according to an embodiment.

Referring to FIG. 4, an operation of measuring the wafer W may be sequentially performed. FIG. 4 may illustrate an operation in which a first measurement area M1, a second measurement area M2, a third measurement area M3, and a fourth measurement area M4 are sequentially measured. Each of the measurement areas M1 to M4 may include a plurality of measurement points. In FIG. 4, for convenience of explanation, it is shown that nine measurement points are included in each of the measurement areas, but the inventive concept is not limited thereto, and the number of measurement areas and the number of measurement points may be determined differently. When the first to fourth measurement areas are measured, intervals D1 to D4 between adjacent measurement points within a measurement area may not be constant or equal, for example, due to vibrations of the wafers.

FIG. 5 is a diagram for explaining a wafer measurement point according to an embodiment.

As shown in FIG. 5, a plurality of measurement points MP may be located on a wafer W. The measurement points may be represented by coordinates on an X-axis and a Y-axis plane perpendicular to the X-axis. As shown in FIG. 4, the wafer level map may be generated by measuring the wafer W for each measurement area. For example, the measurement equipment 200 of FIG. 1 may sequentially measure the wafers 100 at each measurement area to generate the wafer level maps WLM_1 to WLM_N.

FIG. 6 is a diagram for explaining a composite wafer level map according to an embodiment. For example, the composite wafer level map SW of FIG. 6 depicts data generated from 3 lots in a photo process, with 20 wafers included in each lot. The three lots may be referred to as Lot A, Lot B, and Lot C, and each lot may contain wafers #1 through #20. The composite wafer level map SW shown in FIG. 6 may be a diagram showing locations where defects occur, or data points, among a total of 60 wafers included in Lot A, Lot B, and Lot C. As shown in FIG. 6, P1 may indicate a defect at the x1, y1, and z1 coordinates (data point) of the wafer No. 2 of A lot. P2 may indicate a defect at the x2, y2, and z2 coordinates of the wafer No. 7 of B lot. P3 may indicate a defect at the x3, y3, and z3 coordinates of the wafer No. 15 of C lot.

FIG. 7 is a diagram for explaining an operation of dividing a composite wafer level map into grid areas according to an embodiment. Referring to FIG. 7, the composite wafer map SW may be divided into a grid area GA for every X-axis interval DX on the X-axis and Y-axis interval DY on the Y-axis. In some embodiments, the composite wafer map SW may be divided into the X-axis interval DX from a minimum value Xmin of X-axis measurement points to a maximum value Xmax of X-axis measurement points. The X-axis interval DX may be a multiple of the X-axis average interval of the measurement points MP shown in FIG. 5. For example, in the case that the X-axis average interval of the measurement points MP shown in FIG. 5 is 10 um, the composite wafer map SW may be divided into 30 um intervals on the X-axis, where 30 um is three times 10 um. In the example, X-axis interval DX may be 30 um wide.

In some embodiments, the maximum value Xmax, the minimum value Xmin, and the average interval of the X-axis measurement points may be determined based on any one of wafers used to generate the composite wafer level map SW. In another embodiment, the maximum value Xmax, the minimum value Xmin, and the average interval of the X-axis measurement points may be determined based on multiple or all wafers used to generate the composite wafer level map SW.

The Y-axis interval may be multiple of the Y-axis average interval of the measurement points MP shown in FIG. 5. For example, in the case that the Y-axis average interval of the measurement points MP shown in FIG. 5 is 5 μm, the composite wafer map SW may be divided into 10 μm intervals on the Y-axis, where 10 μm is twice 5 μm. In the example, Y-axis interval DY may be 10 μm high. In some embodiments, the maximum, the minimum, and the average interval of the Y-axis measurement points may be based on any one of wafers used to generate the composite wafer level map SW. In another embodiment, the maximum value, the minimum value, and the average interval of the Y-axis measurement points may be based on one or more wafers used to generate the composite wafer level map SW.

However, this is merely an example, and the intervals dividing the composite wafer map SW on the X-axis and Y-axis may be determined differently.

FIG. 8 is a flowchart illustrating a method of dividing a wafer level map into grid areas according to an embodiment. FIG. 8 may be described with reference to FIG. 5 and FIG. 7.

In operation S131, the first axis grid area may be divided by a multiple of the average interval of the first axis measurement points from the minimum value of the first axis measurement points to the maximum value of the first axis measurement points. The first axis may exemplarily mean the X axis of FIG. 5. For example, the minimum value of the first axis measurement points may be 1 mm and the maximum value may be 300 mm. In the case that the average interval of measurement points on the first axis is 10 μm, the composite wafer map SW may be divided by a multiple of 10 μm on the first axis. For example, the composite wafer map SW may be divided by an X-axis interval DX of 50 μm, which is 5 times 10 μm, on the first axis.

In operation S132, the second axis grid area may be divided by a multiple of the second axis average interval from the minimum value of the second axis measurement points to the maximum value of the second axis measurement points. The second axis may illustratively mean the Y axis of FIG. 5. For example, the minimum value of the second axis measurement points may be 1 mm and the maximum value may be 300 mm. In the case that the average interval of measurement points on the second axis is 5 μm, the composite wafer map SW may be divided by a multiple of 5 μm on the second axis. For example, the composite wafer map SW may be divided by a Y-axis interval DY of 10 um, which is twice 5 um, on the second axis. However, this is merely exemplary, and the interval dividing the composite wafer map SW on the first axis and the second axis may be determined differently.

FIG. 9 is a diagram for explaining an operation of obtaining target grid areas according to an embodiment.

The composite wafer map SW may include a center area CA and an edge area EA. The center area CA may refer to grid areas adjacent to the center point CT of the composite wafer map SW. The edge area EA may refer to grid areas farther from the center point CT than the center area CA. The edge area EA may refer to grid areas around the center area CA. The number of defect points per unit area of the center area CA and the edge area EA may be different. In other words, during a photo process, the center area CA close to the center point CT may have a small number of defect points per unit area, whereas the edge area EA relatively far from the center point CT may have a large number of defect points per unit area. Criterion for determining a target grid area in the edge area EA and the center area CA may be determined differently. For example, compared to the edge area EA, the center area CA may be classified as a target grid area even though the center area CA includes fewer defect points.

Specifically, in the case that the unique value of the grid area included in the center area CA is equal to or greater than a first filtering reference value, the corresponding grid area may be classified as a target grid area. For example, the first filtering reference value may include information on at least one of the number of unique lots, the number of unique wafers, or the number of unique data points. For example, in case that the filtering reference value is set based on the number of unique wafers, the first filtering reference value may be three. In other words, among the grid areas of the center area CA, grid areas in which the number of defective wafers, i.e., the number of unique wafers, is three or more, may be classified as a target grid area. However, this is merely exemplary, and the first filtering reference value may be set to the number of defective lots or the number of defective points, that is, the number of unique data points.

In the case that the unique value of the grid area included in the edge area EA is equal to or greater than the second filtering reference value higher than the first filtering reference, the corresponding grid area may be classified as a target grid area. For example, the second filtering reference value may be 5. In other words, among grid areas of the edge area EA, grid areas in which the number of defective wafers, that is, the number of unique wafers is 5 or more, may be classified as a target grid area. However, this is merely exemplary, and the second filtering reference value may be set to the number of defective lots or the number of defective points.

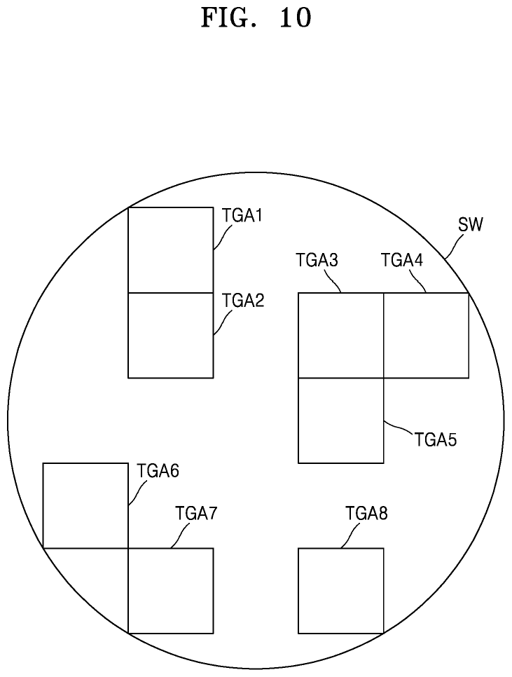

FIG. 10 is a diagram illustrating target grid areas according to an embodiment.

FIG. 10 may show grid areas having a unique value equal to or greater than the first filtering reference value among grid areas included in the center area CA of FIG. 9 and grid areas having a unique value equal to or greater than the second filtering reference value among grid areas included in the edge area EA of FIG. 9. In the example of FIG. 10, there are eight target grid areas shown, including a first target grid area TGA1, a second target grid area TGA2, a third target grid area TGA3, a fourth target grid area TGA4, a fifth target grid area TGA5, a sixth target grid area TGA6, a seventh target grid area TGA7, and an eighth target grid area TGA8, but this is an example, and the number of target grid areas is not limited thereto. The target grid areas may be grid areas having unique value equal to or greater than the first filtering reference value or the second filtering reference value, and may refer to grid areas that are subject to defect analysis.

FIG. 11A and FIG. 11B are diagrams illustrating target grid clusters according to embodiments.

FIG. 11A and FIG. 11B may show that adjacent target grid areas are grouped into target grid clusters depending on a neighboring range. The neighboring range may mean a criterion for determining adjacent target grid areas. In some embodiments, the neighboring range may indicate a case of target grid areas being adjacent by a plane or sharing a plane. In another embodiment, the neighboring range may indicate a case of being adjacent by a plane or a case of target grid areas being adjacent by a point. For example, target grid areas that sharing a corner point may be grouped into a target cluster.

FIG. 11A illustrates that target grid areas may be grouped into a target grid cluster in the case that the neighboring range is adjacent by a plane. FIG. 11B illustrates that the target grid areas may be grouped into a target grid cluster in the case that the neighboring ranges are adjacent by a plane or by a point.

Referring to FIG. 10 and FIG. 11A, since the first target grid area TGA1 and the second target grid area TGA2 are adjacent to each other by a plane, the first target grid area TGA1 and the second target grid area TGA2 may be grouped into a first target grid cluster TGC1. In addition, since the third target grid area TGA3 is adjacent to the fourth grid area TGA4 and the fifth grid area TGA5 by a plane, accordingly, the third target grid area TGA3, the fourth grid area TGA4, and the fifth grid area TGA5 may be grouped into a second target grid cluster TGC2. Since the sixth grid area TGA6 is not adjacent to the seventh grid area TGA7 by a plane, the sixth grid area TGA6 and the seventh grid area TGA7 may be labeled as a third target grid cluster TGC3 and a fourth target grid cluster TGC4, respectively. The eighth grid area TGA8 may be labeled as a fifth target grid cluster TGC5 since there is no grid area adjacent to the eighth grid area TGA8.

Referring to FIG. 10 and FIG. 11B, since the first target grid area TGA1 and the second target grid area TGA2 are adjacent by a plane, the first target grid area TGA1 and the second target grid area TGA2 may be grouped into a first target grid cluster TGC1′. In addition, since the third target grid area TGA3 is adjacent to the fourth grid area TGA4 and the fifth grid area TGA5 by a plane, accordingly, the third target grid area TGA3, the fourth grid area TGA4, and the fifth grid area TGA5 may be grouped into a second target grid cluster TGC2′. The sixth grid area TGA6 is not adjacent to the seventh grid area TGA7 by a plane, but is adjacent to the seventh grid area TGA7 by a point, so the sixth grid area TGA6 and the seventh grid area TGA7 may be grouped into a third target grid cluster TGC3′. The eighth grid area TGA8 may be labeled as a fifth target grid cluster TGC4′ since there is no grid area adjacent by a plane or by a point.

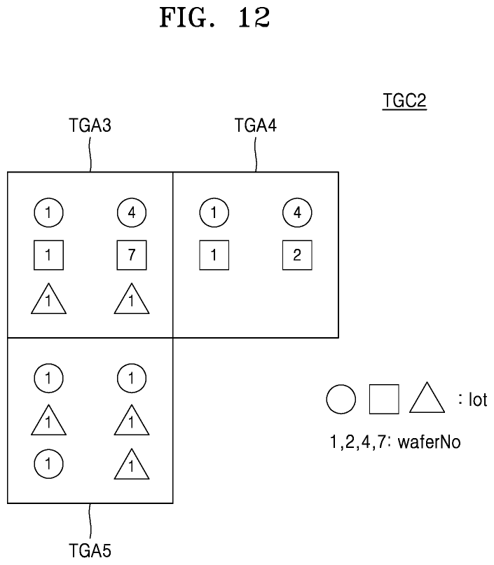

FIG. 12 is a diagram for explaining an operation of obtaining detection priorities of target grid clusters according to an embodiment.

FIG. 12 illustrates an example representation of the second target grid cluster TGC2 of FIG. 11A.

The second target grid cluster TGC2 may include the third target grid area TGA3, the fourth target grid area TGA4, and the fifth target grid area TGA5.

The third target grid area TGA3, the fourth target grid area TGA4, and the fifth target grid area TGA5 may include the defect points described herein with reference to FIG. 6. Each defect point may include unique value. In other words, each defect point may include at least one of a unique lot, a unique wafer, or a unique data point. The detection priorities of the target grid cluster may be determined according to the unique value included in the target grid cluster. For example, the detection priorities of the target grid cluster may be determined according to score function values of the target grid clusters. The score function may be expressed, for example, by the following mathematical equation, which may be used to calculate score function values.

Score=a*n(lot)−|b*n(wafer)−c*n(lot)|

In the score function, a, b, and c may be positive real numbers, n(lot) may be the average number of unique lots in the target grid cluster, and n(wafer) may be the average number of unique wafers in the target grid cluster. Figures within the target grid area may indicate unique lots, and numbers within the figure may indicate wafer numbers in which defects occur in the corresponding unique lot. In addition, the location of the figure may represent a location where the defect occurs in the target grid area.

Referring to FIG. 12, the number of unique lots in the third target grid area TGA3 may be three, and the number of unique wafers may be five. The number of unique lots of the fourth target grid area TGA4 may be two, and the number of unique wafers may be four. The number of unique lots of the fifth target grid area TGA5 may be two, and the number of unique wafers may be two. Accordingly, the average number of lots of the second target grid cluster TGC2 is (3+2+2)/3=2.33. In addition, the average number of wafers of the second target grid cluster TGC2 is (5+4+3)/3=3.66. The values of a, b, and c may vary depending on the photo process. Exemplarily, in case of a=4, b=1, and c=5, the score function value of the second target grid cluster may be determined as Score=4*2.33−|1*3.66-5*2.33|, or 1.33.

FIG. 12 shows a process of obtaining the score function value of the second target grid cluster TGC2 as an example among the target grid clusters of FIG. 11A, but the score function values of the remaining target grid clusters not shown in FIG. 12 may also be understood in view of FIG. 12.

In some embodiments, wafer defect detection priorities may be determined according to the score function values of target grid clusters. For example, in the case that the score function value of the second target grid cluster TGC2 is larger than the score function value of the first target grid cluster TGC1, the wafer defect detection priority of the second target grid cluster TGC2 may be higher than the wafer defect detection priority of the first target grid cluster TGC1.

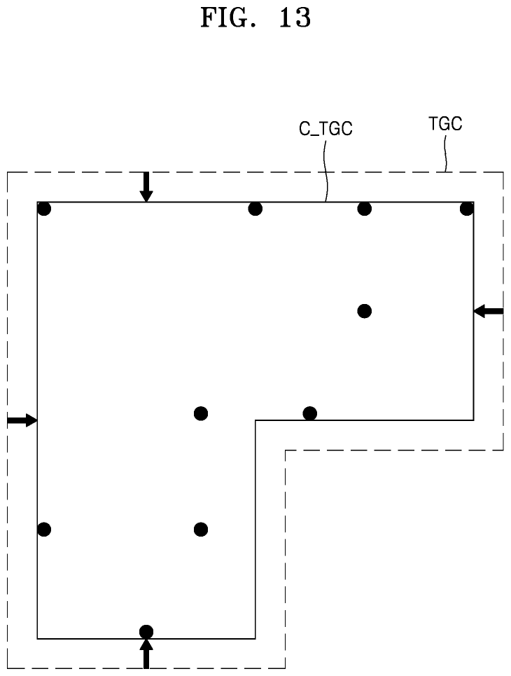

FIG. 13 is a diagram for explaining an operation of correcting a target grid cluster according to an embodiment.

As described above with reference to FIG. 7 and FIG. 8, the grid area may be set as multiple of the average interval of measurement points. Accordingly, the target grid cluster TGC in which target grid areas are grouped may also be set as multiple of the average interval of measurement points. Therefore, an error or difference may occur between the boundary of the target grid cluster TGC and an actual defect point. The target grid cluster TGC may be corrected to a location of the actual defect point, as shown in FIG. 13, to compensate for the error. In other words, the target grid cluster TGC may be corrected to correspond to the wafer level map including defect points. The target grid cluster TGC may be resized to the corrected target grid cluster C_TGC after a correction.

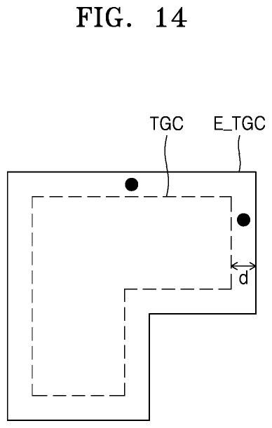

FIG. 14 is a diagram for explaining an operation of performing a close-range search according to an embodiment.

As described above with reference to FIG. 9 and FIG. 10, an area having a unique value less than the first filtering reference value among the center areas and an area having a unique value less than the second filtering reference value among the edge areas may contain defect points, but may not be classified as a target grid area. Accordingly, one or more defect points may be located in an area surrounding the target grid cluster TGC. The close-range search operation may be performed, and defect points located in the surrounding area may be included in the target grid cluster TGC. The close-range search operation may be an operation of searching for one or more defect points located within a search distance d from the target grid cluster TGC. In the case that a defect point is located within the close-range search distance d, the target grid cluster TGC may be extended to an area including the defect point. In other words, in the case that a defect point is located around the target grid cluster TGC during a close-range search operation, the target grid cluster TGC may be extended to the location of the defect point, and the defect point may be included in the target grid cluster. After the close-range search operation, the size of the target grid cluster TGC may be adjusted to the expanded target grid cluster E_TGC.

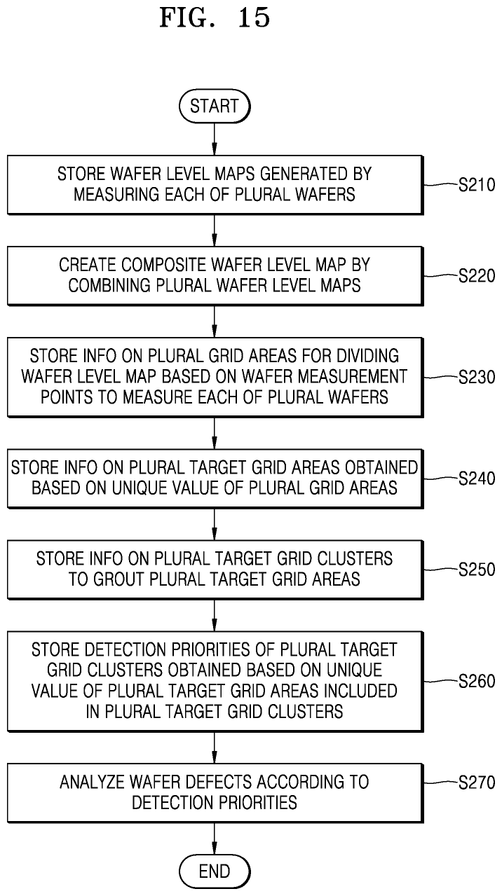

FIG. 15 is a flowchart illustrating a method of detecting wafer defects according to an embodiment. FIG. 15 may be described with reference to FIG. 1.

Referring to FIG. 15, a method of detecting wafer defects according to an embodiment may include operations S210 to S270.

In operation S210, the wafer level maps WLM_1 to WLM_N generated by measuring each of the plurality of wafers 100 may be stored. The plurality of wafer level maps WLM_1 to WLM_N may include wafer level data, and the wafer level data may include the locations and heights of the defects.

In operation S220, a composite wafer level map may be generated by combining the plurality of wafer level maps WLM_1 to WLM_N. The composite wafer level map may include data indicating the locations of defect points occurring on each of the plurality of wafers. The composite wafer level map may be displayed showing the locations of defect points occurring on each of the plurality of wafers on a plane.

In operation S230, information about a plurality of grid areas may be stored. The information about the plurality of grid areas may be used for dividing the composite wafer level map based on a plurality of wafer measurement points obtained by measuring each of the plurality of wafers 100. The wafer measurement points obtained by measuring the plurality of wafers 100 may indicate measured locations on the wafer as shown in FIG. 5.

In operation S240, information about a plurality of target grid areas may be stored. The information about the plurality of target grid areas may be obtained based on the unique value of the plurality of grid areas. The composite wafer map may include a center area and an edge area. Among the grid areas, in the case that the unique value of the center area is equal to or greater than the first filtering reference value or the unique value of the edge area is equal to or greater than the second filtering reference value higher than the first filtering reference value, the grid area may be classified as a target grid area. The unique value may include at least one of the number of unique lots of wafers, the number of unique wafers in the unique lots, or the number of unique data points on the wafers.

In operation S250, information about a plurality of target grid clusters may be stored. The target grid clusters may be created by grouping adjacent target grid areas among the target grid areas. In some embodiments, target grid areas contiguous by a plane may be grouped into a target grid cluster. In an embodiment, target grid areas contiguous by a point may be grouped into a target grid cluster. In another embodiment, a target grid cluster may include target grid areas adjacent by a plane and target grid areas adjacent by a point.

In operation S260, detection priorities of the plurality of target grid clusters may be stored based on the unique values of the plurality of target grid areas included in the plurality of target grid clusters. In the case that the number of defects in a target grid area included in the target grid cluster is large, the unique value of the target grid area may also be large. In other words, the detection priority of a target grid cluster may be related to the number of defects of the target grid cluster. For example, the detection priority of a target grid cluster having many defects may be higher than the detection priority of another target grid cluster having few defects.

In operation S170, the plurality of target grid clusters and the detection priority for each of the plurality of target grid clusters may be output to a wafer defect analysis system for analyzing the wafer defects based on the detection priorities. In operation S270, the defects of the wafers may be analyzed by the wafer defect analysis system according to the detection priorities of the target grid clusters. For example, operation S270 may include selecting a set of wafer defects to analyze among the wafer defects based on the detection priorities. By detecting the wafer defects from a target grid cluster with a highest priority, it may be possible to detect and track processes and process equipment that may cause defects on the rear surface of the wafer. Further, it may be possible to track processes and process equipment that may cause defects on the rear surface of the wafer at an early stage, for example, following a photo process.

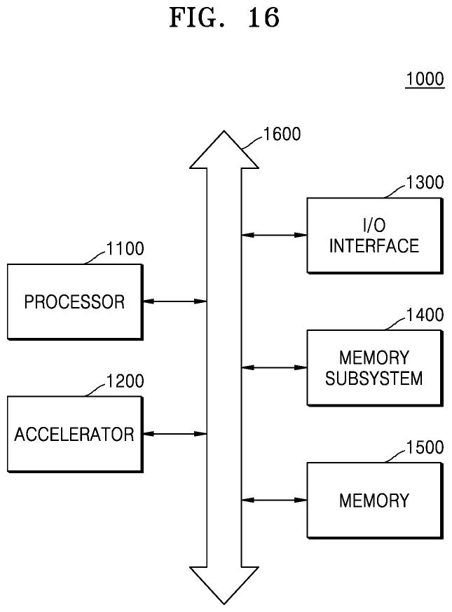

FIG. 16 is a diagram illustrating a defect cluster detection apparatus according to an embodiment.

Specifically, the defect cluster detection apparatus of FIG. 16 may correspond to the defect cluster detection apparatus 300 of FIG. 1. FIG. 16 may be described with reference to FIG. 1, and repetitious descriptions thereof may be omitted.

As shown in FIG. 16, the defect cluster detection apparatus may include a processor 1100, an accelerator 1200, an input/output interface 1300, a memory subsystem 1400, a memory 1500, and a bus 1600. The processor 1100, the accelerator 1200, the input/output interface 1300, the memory subsystem 1400, and the memory 1500 may communicate with each other via the bus 1600. In some embodiments, the defect cluster detection apparatus may be a SoC with components implemented on a single chip, and the memory 1500 may be located at the outside of a SoC. In some embodiments, at least one of the components shown in FIG. 12 may be omitted from the defect cluster detection apparatus.

The processor 1100 may control the operation of the defect cluster detection apparatus at a top layer, and may control other components of the defect cluster detection apparatus.

In some embodiments, the processor 1100 may include two or more processing cores. As described above with reference to the drawings, the processor 1100 may process various measures necessary for the operation of the defect cluster detection apparatus to detect the first defect point on the wafer.

The accelerator 1200 may be designed to perform a designated function at high speed. For example, the accelerator 1200 may provide data generated by processing data received from the memory subsystem 1400 to the memory subsystem 1400.

The input/output interface 1300 may provide an interface for receiving an input from the outside of the defect cluster detection apparatus and providing an output to the outside of the defect cluster detection apparatus. For example, the defect cluster detection apparatus may receive the first to Nth wafer level maps from the outside through the input/output interface 1300.

The memory subsystem 1400 may be accessed by other components coupled to the bus 1600. In some embodiments, the memory subsystem 1400 may include volatile memory, such as DRAM and SRAM, or may include non-volatile memory, such as flash memory and resistive random-access memory (RRAM). Additionally, in some embodiments, the memory subsystem 1400 may provide an interface to the memory 1500. The memory 1500 may be a storage medium that does not lose data even when power is cut off. For example, the memory 1500 may include a semiconductor memory device such as a non-volatile memory, or may include any storage medium such as a magnetic card/disk or an optical card/disk. In an embodiment, the memory 1500 may include a program for executing the defect cluster detection method described above with reference to FIGS. 1 to 15.

According to an embodiment, the defect cluster detection apparatus may be used as a wafer defect analysis system. For example, the memory 1500 may include a program for executing the wafer defect analysis method described above with reference to operation S170 of FIG. 2 or operation S270 of FIG. 15.

The bus 1600 may operate based on one of a variety of bus protocols. The various bus protocols may include at least one of the Advanced Microcontroller Bus Architecture (AMBA) protocol, Universal Serial Bus (USB) protocol, Multi-Media Card (MMC) protocol, Peripheral Component Interconnection (PCI) protocol, PCI-Express (PCI-E) protocol, Advanced Technology Attachment (ATA) protocol, Serial-ATA protocol, Parallel-ATA protocol, Small Computer Small Interface (SCSI) protocol, Enhanced Small Disk Interface (ESDI) protocol, Integrated Drive Electronics (IDE) protocol, Mobile Industry Processor Interface (MIPI) protocol, Universal Flash Storage (UFS) protocol, or the like.

As above, embodiments are disclosed in the drawings and specifications. Although embodiments are described using specific terms in this specification, the specific terms are only used for the purpose of explaining the inventive concept, and are not intended to limit the meaning or scope of the disclosure as recited in the patent claims accordingly. Therefore, those of ordinary skill in the art will understand that various modifications and equivalent other embodiments are possible therefrom. Accordingly, the true technical scope of protection of the inventive concept should be determined by the appended claims.

While the inventive concept has been particularly shown and described with reference to embodiments thereof, it will be understood that various changes in form and details may be made therein without departing from the spirit and scope of the following claims.

What is claimed is:

1. A method of detecting clusters of defects, the method comprising:
measuring each of a plurality of wafers to obtain a plurality of wafer level maps of a plurality of wafer measurement points;
creating a composite wafer level map by combining the plurality of wafer level maps;
dividing the composite wafer level map into a plurality of grid areas;
obtaining a plurality of target grid areas from the plurality of grid areas using unique values of the plurality of grid areas;
grouping the plurality of target grid areas into a plurality of target grid clusters corresponding to the clusters of defects; and
obtaining a detection priority for each of the plurality of target grid clusters based on the unique values of the plurality of target grid areas included in the plurality of target grid clusters.

2. The method of claim 1, further comprising outputting the plurality of target grid clusters and the detection priority for each of the plurality of target grid clusters to a wafer defect analysis system for analyzing the wafer defects in an order based on the detection priorities.

3. The method of claim 1, wherein the measuring of each of a plurality of wafers to obtain the plurality of wafer level maps includes:
acquiring height data of the plurality of wafers at the plurality of wafer measurement points on a rear surface of the plurality of wafers; and
generating the plurality of wafer level maps indicating the wafer defects at positions of the plurality of wafer measurement points having height data equal to or greater than a threshold height.

4. The method of claim 1, wherein the plurality of wafer measurement points are located on a first axis and a second axis perpendicular to the first axis, and the plurality of grid areas are divided based on a first axis average interval between adjacent ones of the plurality of wafer measurement points on the first axis and a second axis average interval between adjacent ones of the plurality of wafer measurement points on the second axis.

5. The method of claim 4, wherein the dividing of the composite wafer level map into the plurality of grid areas comprises:
dividing the composite wafer map by a multiple of the first axis average interval from a minimum value of the first axis measurement points to a maximum value of the first axis measurement points; and
dividing the composite wafer map by a multiple of the second axis average interval from a minimum value of the second axis measurement points to a maximum value of the second axis measurement points.

6. The method of claim 1, wherein the unique values of the plurality of target grid areas includes at least one of a number of unique data points, a number of unique wafers of the plurality of wafers, or a number of unique lots of the plurality of wafers.

7. The method of claim 1, wherein the composite wafer map includes a center area and an edge area, and
wherein the plurality of target grid areas of the center area correspond to ones of the plurality of grid areas having the unique values equal to or greater than a first filtering reference value, and the plurality of target grid areas of the edge area correspond to ones of the plurality of grid areas having the unique values equal to or greater than a second filtering reference value, wherein the second filtering reference value is higher than the first filtering reference value.

8. The method of claim 1, wherein the grouping of the plurality of target grid areas into the plurality of target grid clusters includes grouping adjacent target grid areas of the plurality of target grid areas into a same target grid cluster of the plurality of target grid clusters.

9. The method of claim 8, further comprising correcting a size of at least one of the target grid clusters to correspond to the wafer level map.

10. The method of claim 1, wherein the obtaining of the detection priority for each of the plurality of target grid clusters includes obtaining the detection priorities using a value of a score function of each of the plurality of target grid clusters, and the value of the score function is calculated by an equation:
Score=a*n(lot)−|b*n(wafer)−c*n(lot)|,
wherein n(lot) is an average number of unique lots in the target grid cluster, and n(wafer) is an average number of unique wafers in the target grid cluster.

11. The method of claim 1, further comprising expanding an area of at least one of the plurality of target grid clusters to include a location of at least one of the plurality of wafer measurement points upon determining that the at least one of the plurality of wafer measurement points has at least a threshold height and is located within a search distance to at least one of the plurality of target grid clusters.

12. An apparatus for detecting clusters of wafer defects, the apparatus comprising:
a memory storing a program for detecting the wafer defects; and
a processor configured to execute the program stored in the memory to:
measure a height at each of a plurality of wafer measurement points on each of a plurality of wafers to obtain a plurality of wafer level maps;
create a composite wafer level map by combining the plurality of wafer level maps;
divide the composite wafer level map into a plurality of grid areas;
obtain a plurality of target grid areas from the plurality of grid areas using unique values of the plurality of grid areas;
group the plurality of target grid areas into a plurality of target grid clusters corresponding to the clusters of defects;
obtain a detection priority for each of the plurality of target grid clusters based on the unique values of the plurality of target grid areas included in the plurality of target grid clusters; and
select a set of wafer defects to analyze among the wafer defects based on the detection priorities.

13. The apparatus of claim 12, wherein the unique values include at least one of a number of unique data points, a number of unique wafers of the plurality of wafers, or a number of unique lots of the plurality of wafers.

14. The apparatus of claim 12, wherein the composite wafer map includes a center area and an edge area, and the plurality of target grid areas of the center area correspond to ones of the plurality of grid areas having the unique values equal to or greater than a first filtering reference value, and the plurality of target grid areas of the edge area correspond to ones of the plurality of grid areas having the unique values equal to or greater than a second filtering reference value, wherein the second filtering reference value is higher than the first filtering reference value.

15. The apparatus of claim 12, wherein the processor is further configured to:
group adjacent target grid areas of the plurality of target grid areas into a same target grid cluster of the plurality of target grid clusters; and
correct a size of the target grid cluster to correspond to the wafer level map.

16. The apparatus of claim 12, wherein the processor is further configured to acquire the detection priority for each of the plurality of target grid clusters using a value of a score function of each of the plurality of target grid clusters, and calculate the value of the score using an average number of unique lots in the target grid cluster, and an average number of unique wafers in the target grid cluster.

17. The apparatus of claim 12, wherein the processor is further configured to expand an area of at least one of the plurality of target grid clusters to a location of at least one of the plurality of wafer measurement points upon determining that the at least one of the plurality of wafer measurement points has at least a threshold height and is located within a search distance to at least one of the plurality of target grid clusters.

18. A method of detecting clusters of defects, the method comprising:
storing a plurality of wafer level maps indicating locations of wafer defects on rear surfaces of a plurality of wafers;
creating a composite wafer level map by combining the plurality of wafer level maps;
storing information of a plurality of grid areas dividing the composite wafer level map;
storing information of a plurality of target grid areas having unique values among the plurality of grid areas;
storing information of a plurality of target grid clusters corresponding to groups of the plurality of target grid areas and corresponding to the clusters of defects;
storing detection priorities of the plurality of target grid clusters obtained using the unique values of the plurality of target grid areas included in the plurality of target grid clusters; and
selecting a set of wafer defects to analyze among the wafer defects according to the detection priorities.

19. The method of claim 18, wherein the composite wafer map includes a center area and an edge area, and the plurality of target grid areas of the center area correspond to ones of the plurality of grid areas having the unique values equal to or greater than a first filtering reference value, and the plurality of target grid areas of the edge area correspond to ones of the plurality of grid areas having the unique values equal to or greater than a second filtering reference value, wherein the second filtering reference value is higher than the first filtering reference value.

20. The method of claim 18, further comprising expanding an area of at least one of the plurality of target grid clusters to include a location of at least one of the wafer defects upon determining that the at least one of the wafer defects has at least a threshold height and is located within a search distance to at least one of the plurality of target grid clusters.
